(19) United States
(12) Patent Application Publication
(10) Pub. No.: US 2025/0324619 A1
(43) Pub. Date: Oct. 16, 2025

(54) METAL-INSULATOR-METAL CAPACITOR, SEMICONDUCTOR DEVICE HAVING THE SAME AND MANUFACTURING METHOD THEREOF

(71) Applicant: Taiwan Semiconductor Manufacturing Company, Ltd., Hsinchu (TW)

(72) Inventors: Ying-Ju Wu, Hsinchu (TW); Tzu-Ting LIU, Hsinchu (TW); Yi-Shan HSIEH, Hsinchu (TW); Hsiang-Ku SHEN, Hsinchu (TW); Chen-Chiu HUANG, Hsinchu (TW); Feng-Cheng YANG, Hsinchu (TW); Dian-Hau CHEN, Hsinchu (TW)

(73) Assignee: Taiwan Semiconductor Manufacturing Company, Ltd., Hsinchu (TW)

(21) Appl. No.: 18/636,775

(22) Filed: Apr. 16, 2024

(51) Int. Cl. H10D 1/00; H10D 1/68

(52) U.S. Cl. CPC H10D 1/042; H10D 1/716

(57) ABSTRACT

A manufacturing method of a metal-insulator-metal (MIM) capacitor is provided, including the following steps. A conductive metal layer is formed on a substrate. A patterned dielectric layer is formed on the substrate. The patterned dielectric layer has a plurality of trenches, and the conductive metal layer is exposed at the bottom of the trenches. A MIM structure is formed above the patterned dielectric layer and in the trenches. The MIM structure includes an upper electrode layer, an insulating layer and a lower electrode layer. The insulating layer is located on the upper electrode layer and the lower electrode layer, wherein the lower electrode layer covers the sidewalls and bottoms of the trenches, and the lower electrode layer is electrically connected to the conductive metal layer.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies, such as a metal-insulator-metal (MIM) capacitor, also need to be improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a semiconductor device according to an embodiment of the present disclosure.

FIGS. 2A to 2G respectively are schematic diagrams of a method of manufacturing a semiconductor device according to an embodiment of the present disclosure.

FIG. 3 is a diagram illustrating the relationship between the operating frequency and the admittance characteristics of a MIM capacitor according to an embodiment of the present disclosure.

FIG. 4 is a flow chart of a method of manufacturing a MIM capacitor according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides various embodiments of a three-dimensional (3D) MIM structure and methods of forming the same. In some embodiments, 3D MIM structures are provided in a back-end-of-line (BEOL) of semiconductor devices, where various components in a substrate are interconnected with metallization structures and via structures in corresponding dielectric layers. This approach allows the construction of 3D MIM capacitors between multiple deep via structures in BEOL.

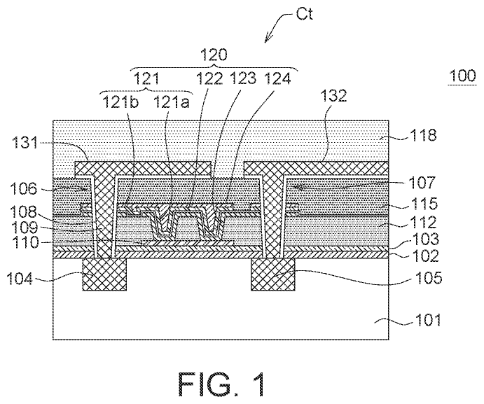

Referring to FIG. 1, a schematic diagram of a semiconductor device 100 according to an embodiment of the present disclosure is shown. The lower portion of the semiconductor device 100 may include a substrate 101, a first conductive feature 104, and a second conductive feature 105. In addition, the upper portion of the semiconductor device 100 may include a first via structure 106, a second via structure 107, a conductive metal layer 110 and a metal-insulator-metal (MIM) structure 120.

The semiconductor device 100 may be included in a microprocessor, memory cell, and/or other integrated circuit (IC). Also, FIG. 1 is simplified for a better understanding of the concepts of the present disclosure. Although the figures illustrate the semiconductor device 100, it is understood the IC may comprise a number of other devices such as resistors, capacitors, inductors, fuses, etc., which are not shown in FIG. 1, for purposes of clarity of illustration.

Although the semiconductor device 100 in the illustrated embodiment of FIG. 1 includes only two conductive features (e.g., 104, 105), it is understood that the illustrated embodiment of FIG. 1 and the following figures are merely provided for illustration purposes. Thus, the semiconductor device 100 may include any desired number of conductive features while remaining within the scope of the present disclosure.

In some embodiments, the substrate 101 includes a silicon substrate. Alternatively, the substrate 101 may include other elementary semiconductor material such as, for example, germanium. The substrate 101 may also include a compound semiconductor such as silicon carbide, gallium arsenic, indium arsenide, and indium phosphide. The substrate 101 may include an alloy semiconductor such as silicon germanium, silicon germanium carbide, gallium arsenic phosphide, and gallium indium phosphide. In one embodiment, the substrate 101 includes an epitaxial layer. For example, the substrate 101 may have an epitaxial layer overlying a bulk semiconductor. Furthermore, the substrate 101 may include a semiconductor-on-insulator (SOT) structure. For example, the substrate 101 may include a buried oxide (BOX) layer formed by a process such as separation by implanted oxygen (SIMOX) or other suitable technique, such as wafer bonding and grinding.

In some embodiments, the substrate 101 also includes various p-type doped regions and/or n-type doped regions, implemented by a process such as ion implantation and/or diffusion. Those doped regions include n-well, p-well, lightly doped region (LDD), heavily doped source and drain (S/D), and various channel doping profiles configured to form various integrated circuit (IC) devices, such as a complimentary metal-oxide-semiconductor field-effect transistor (CMOSFET), imaging sensor, and/or light emitting diode (LED). The substrate 101 may further include other functional features such as a resistor or a capacitor formed in and on the substrate. The substrate 101 further includes lateral isolation features provided to separate various devices formed in the substrate 101, for example shallow trench isolation (STI). The various devices in the substrate 101 further include silicide disposed on S/D, gate and other device features for reduced contact resistance and enhance process compatibility when coupled between devices through local interconnections.

In an embodiment, the first and second conductive features 104 and 105 can be a source, drain or gate electrode. Alternatively, the conductive features 104 and 105 may be a silicide feature disposed on a source, drain or gate electrode typically from a sintering process introduced by at least one of the processes including thermal heating, laser irradiation or ion beam mixing. The silicide feature may be formed on polysilicon gate (typically known as “polycide gate”) or on source/drain (typically known as “salicide”) by a self-aligned silicide technique. In another embodiment, the first and second conductive features 104 and 105 and may include an electrode of a capacitor or one end of a resistor.

The first and second via structures 106 and 107 may be a conductive plug. In some further embodiments, the semiconductor device 100 may include a barrier layer 108 surrounding sidewalls and bottom surface of the first and second via structures 106 and 107.

In some embodiments, the first and second via structures 106 and 107 may include a metal material 109 such as copper (Cu) or the like. In some other embodiments, the first and second via structures 106 and 107 may include other suitable metal materials (e.g., gold (Au), cobalt (Co), silver (Ag), etc.) and/or conductive materials (e.g., polysilicon) while remaining within the scope of the present disclosure.

In some embodiments, the barrier layer 108 includes a conductive material such as a metal, a metal alloy, or a metal nitride, for example, tantalum nitride (TaN), tantalum (Ta), titanium nitride (TiN), titanium (Ti), cobalt tungsten (CoW), tungsten nitride (WN), or the like. The barrier layer 108 may effectively prevent metal atoms from diffusing into the first and second ILD layers 112 and 115 during a metal deposition process to form the first and second via structures 106 and 107, which will be discussed below.

The first and second via structures 106 and 107 may be formed by at least some of the following process steps: using chemical vapor deposition (CVD), physical vapor deposition (PVD), spin-on coating, and/or other suitable techniques to deposit an etch stop layer 102 and a low-k dielectric layer 103, a first ILD layer 112, multi-layers of the MIM structure 120, and a second ILD layer 115 over the substrate 101 with the first and second conductive features 104 and 105; performing one or more patterning processes (e.g., a lithography process, a dry/wet etching process, a soft/hard baking process, and a cleaning process, etc.) to form a via hole 117 passing through the etch stop layer 102, the low-k dielectric layer 103, the first ILD layer 112, the MIM structure 120, and the second ILD layer 115; using CVD, PVD, and/or other suitable techniques to deposit the barrier layer 108 along the sidewalls and bottoms of the via holes 117; using CVD, PVD, E-gun, and/or other suitable techniques to fill the via holes 117 with a metal material 109, and polishing out excessive metal material by a planarization process (e.g., chemical-mechanical polishing) to form the first and second via structures 106 and 107 with the barrier layer 108. In some embodiments, the conductive metal layer 110 may be formed from a conductive material such as titanium nitride (TiN) or the like.

Referring to FIG. 1, the first conductive feature 104 and the second conductive feature 105 are disposed on the substrate 101. In some embodiments, the etch stop layer 102 and the low-k dielectric layer 103 overly the first conductive feature 104 and the second conductive feature 105. The conductive metal layer 110 and the MIM structure 120 are disposed on the low-k dielectric layer 103, and the MIM structure 120 includes an upper electrode layer 121, an insulating layer 122 and a lower electrode layer 123 that are alternately stacked. The insulating layer 122 is located between the upper electrode layer 121 and the lower electrode layer 123. The upper electrode layer 121 and the lower electrode layer 123 are electrically insulated from each other to form a MIM capacitor Ct. The MIM structure 120 may include another conductive metal layer 124 covering the upper electrode layer 121. The conductive metal layer 124 and the conductive metal layer 110 can be made of the same material and have the same function.

In some embodiments, the MIM capacitor comprises a material with a high dielectric constant, e.g., a high-k dielectric material, for example Al₂O₃, HfO₂, SiO₂, La₂O₃, ZrO₃, Ba—Sr—Ti—O, Si₃N₄ and laminate of a mixture thereof. The MIM capacitor can be formed by various processes including deposition a dielectric layer using PVD, CVD and the like, photolithography and a dry/wet etching process. The thickness of this MIM capacitor is controlled by the desired capacitance value, which is a function of the area of the metallization layers and the dielectric constant of the dielectric material of the MIM capacitor. In some embodiments, the thickness of each of the electrode layers of the MIM capacitor can be in a range of a few tens of nanometers to a few hundreds of nanometers, e.g., 20-70 nanometers, and the thickness of the high dielectric constant material can be in a range of 3-8 nanometers.

In some embodiments, when MIM capacitors are used in RF circuits, the dielectric loss may be extremely small and the series resistance of the wiring may be minimized for high frequency applications. This indicates that it is desirable to use short interconnect wires with low specific resistance. As MIM capacitors are constructed using the back-end metallization layers, the process temperature for the MIM capacitors, particularly the deposition temperature of the MIM capacitor, may be low enough to be compatible with the metallization stack and the low-k dielectric layers.

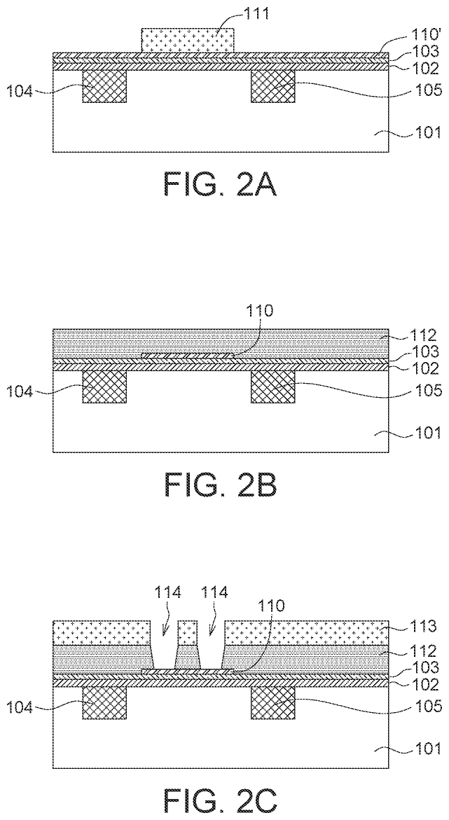

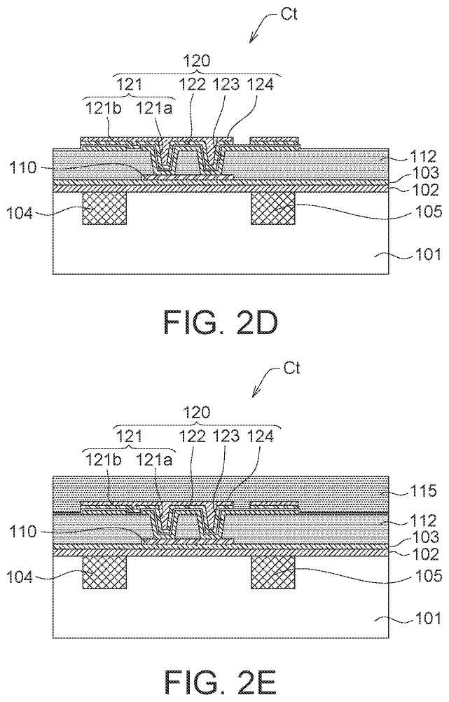

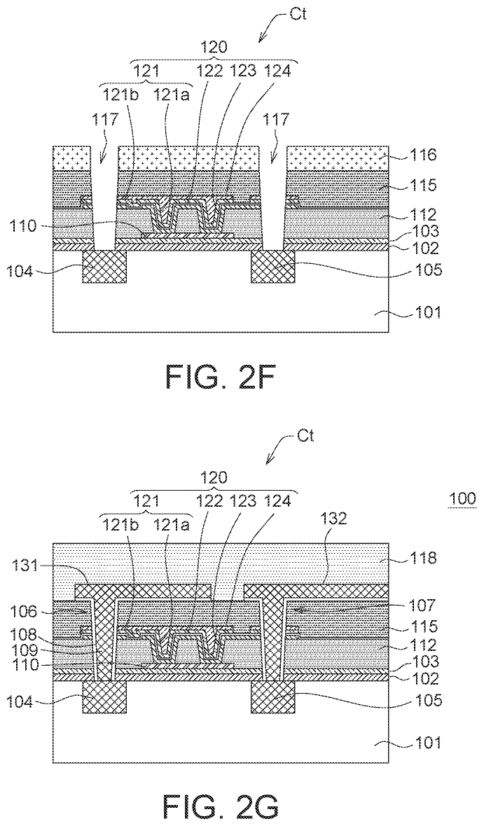

Referring to FIGS. 2A to 2G, schematic diagrams of a method of manufacturing a semiconductor device according to an embodiment of the present disclosure are shown respectively. In FIG. 2A, an etch stop layer 102 and a low-k dielectric layer 103 are deposited on the substrate 101. In addition, a conductive metallic material 110′ is deposited on the low-k dielectric layer 103. Next, a patterned photoresist layer 111 is formed on the conductive metallic material 110′. A portion of the conductive metallic material 110′ covered by the patterned photoresist layer 111 is not etched, and the remaining portion is etched to form a conductive metal layer 110. In FIG. 2B, a first interlayer dielectric (ILD) layer 112 is formed on the conductive metal layer 110. In FIG. 2C, a patterned photoresist layer 113 is formed on the first ILD layer 112. The portion of the first ILD layer 112 not covered by the patterned photoresist layer 113 is etched to form a plurality of trenches 114, and the conductive metal layer 110 is exposed from the bottoms of the trenches 114. In some embodiments, the number of trenches 114 may be two or more, such as 4 to 16, arranged in a straight line or in an array. In one embodiment, only two trenches 114 are shown as an example.

In FIG. 2C, after forming a plurality of trenches 114, the patterned photoresist layer 113 is removed. Then, in FIG. 2D, a lower electrode layer 123 is formed over the first ILD layer 112 and in the trenches 114. The lower electrode layer 123 covers the sidewalls and bottoms of the trenches 114. After that, the insulating layer 122 and the upper electrode layer 121 are formed over the lower electrode layer 123, where the insulating layer 122 and the upper electrode layer 121 can be recessed and filled in the trenches 114 to form the MIM structure 120 in the trenches 114.

In FIG. 2D, the MIM structure 120 formed on the first ILD layer 112 and filled inwardly in the trenches 114 can be called a trench MIM capacitor Ct. However, the present disclosure is not limited to forming only a single capacitor. In other embodiments, the present disclosure can form a vertically stacked capacitor, that is, a structure in which multiple MIM structures 120 are vertically stacked. In some embodiments, the thickness of the trench MIM capacitor Ct may be in the range of 200 nanometers to 1000 nanometers, and the capacitance value of the trench MIM capacitor Ct may be tens or hundreds of microfarads, and the lower electrode layer 123 of the trench MIM capacitor Ct is electrically connected to the conductive metal layer 110, so that the resistance value of the current passing through the lower electrode layer 123 is reduced.

In some embodiments, the conductive metal layer 110, the upper electrode layer 121, and the lower electrode layer 123 may be made of the same material. The conductive metal layer 110, the upper electrode layer 121, and the lower electrode layer 123 may be made of titanium nitride (TiN), titanium aluminum (TiAl), titanium aluminum nitride (TiAlN), tantalum nitride (TaN), or tantalum aluminum (TaAl), tantalum aluminum nitride (TaAlN), tantalum aluminum carbide (TaAlC), tantalum carbon nitride (TaCN), aluminum (Al), tungsten (W), nickel (Ni), titanium (Ti), ruthenium (Ru), Cobalt (Co), platinum (Pt), tantalum carbide (TaC), tantalum silicon nitride (TaSiN), copper (Cu), other refractory metals or other suitable metal materials or combinations thereof.

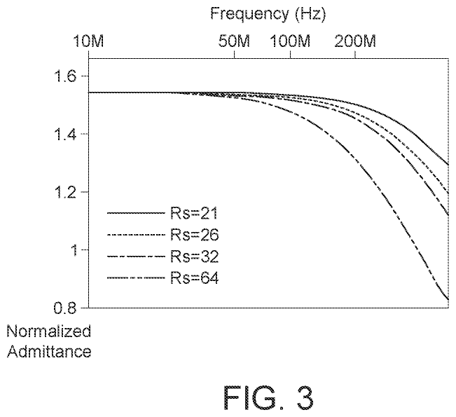

In one embodiment, when the lower electrode layer 123 of the trench MIM capacitor Ct is not electrically connected to the conductive metal layer 110, the current must pass through a tortuous path inside the capacitor Ct in order to reach another side of the capacitor Ct from one side of the capacitor Ct, and thus the resistance value of the current may be too high (for example, up to 64 ohms); however, when the lower electrode layer 123 of the trench MIM capacitor Ct is electrically connected to the conductive metal layer 110, most of the current can directly pass through the conductive metal layer 110 to reach the other side of the capacitor Ct from one side of the capacitor Ct. A small part of the current can enter the inside of the capacitor Ct from the conductive metal layer 110, and then flow from the inside of the capacitor Ct to the conductive metal layer 110. Finally, the current outputs from the other side of the capacitor Ct, so that the resistance value Rs of the current can be reduced to a lower level (such as 21 ohms or less), as shown in FIG. 3. It can be seen from FIG. 3 that by adding the conductive metal layer 110 to accelerate the charging and discharging speed of the capacitor Ct and reduce the resistance value Rs from 64 ohms to 21 ohms, the trench MIM capacitor Ct can have both high capacitance and low resistance characteristics.

As shown in FIG. 2D, in addition to a plurality of vertical electrode portions 121a filled in the trenches 114, the upper electrode layer 121 may also include horizontal electrodes portion 121b laterally connected between the vertical electrode portions 121a. The conductive metal layer 124 and the horizontal electrode portion 121b extend laterally from one side of the MIM structure 120 to the other side of the MIM structure 120 to accelerate the charging and discharging speed of the capacitor Ct.

The above-mentioned trench MIM capacitor Ct with the characteristics of high capacitance and low resistance can be used in high-frequency circuits or hybrid circuits, such as ADC, VOC, filters, LC tanks, and de-coupling circuits, and its operating frequency is, for example, between 50 MHz and 200 MHz, but the present disclosure is not limited thereto. As shown in FIG. 3, when the operating frequency of the capacitor Ct increases from 50 MHz to 200 MHz, the capacitance value of the capacitor Ct will decrease as the operating frequency increases. However, in the present disclosure, the resistance value Rs of the capacitor Ct is reduced from 64 ohms to 21 ohms by adding the conductive metal layer 110 so that the capacitance value of the capacitor Ct can still be maintained at a high level to reduce the extent to which the capacitance value of the capacitor Ct decreases as its operating frequency increases.

In addition, in FIG. 2D, the conductive metal layer 110 is disposed on the low-k dielectric layer 103 with a dielectric constant between 2 and 2.3, and the thickness of the low-k dielectric layer 103 is about hundreds of nanometers, for example between 100 and 200 nanometers. The low-k dielectric layer 103 is, for example, silicon oxide, silicon nitride, silicon carbide, silicon oxynitride or a combination thereof. The low-k dielectric layer 103 isolates the conductive metal layer 110 from the corresponding first and second conductive features 104 and 105, which can reduce a parasitic capacitance effect generated between the conductive metal layer 110 and the corresponding first and second conductive features 104 and 105.

In FIG. 2E, a second ILD layer 115 is formed on the first ILD layer 112. The second ILD layer 115 covers the MIM structure 120 so that the MIM structure 120 is embedded between the first ILD layer 112 and the second ILD layer 115. In FIG. 2F, a patterned photoresist layer 116 is formed on the second ILD layer 115, and an etching process is performed to form a plurality of through holes 117 not covered by the patterned photoresist layer. The through holes 117 penetrate the etch stop layer 102, the low-k dielectric layer 103, the first ILD layer 112, the MIM structure 120 and the second ILD layer 115, and the first and second conductive features 104 and 105 are correspondingly exposed from the bottoms of the through holes 117.

In FIG. 2G, after removing the patterned photoresist layer 116, a conductive material 109 is filled in the through holes 117 and deposited on the corresponding first and second conductive features 104 and 105 to form the first via structure 106 and the second via structure 107. The first via structure 106 is electrically connected to a first conductive line 131, and the second via structure 107 is electrically connected to a second conductive line 132. A passivation layer 118 can be formed on the second ILD layer 115 to protect the first and second conductive lines 131 and 132. In addition, the first via structure 106 is electrically connected to the upper electrode layer 121 of the MIM structure 120, and the second via structure 107 is electrically connected to the lower electrode layer 123 of the MIM structure 120. That is to say, the upper electrode layer 121 is electrically connected to the first via structure 106 but is electrically isolated from the second via structure 107, and the lower electrode layer 123 is electrically connected to the second via structure 107 but is electrically isolated from the first via structure 106 is electrically isolated. Therefore, the upper electrode layer 121 and the lower electrode layer 123 form a MIM capacitor Ct between the first via structure 106 and the second via structure 107.

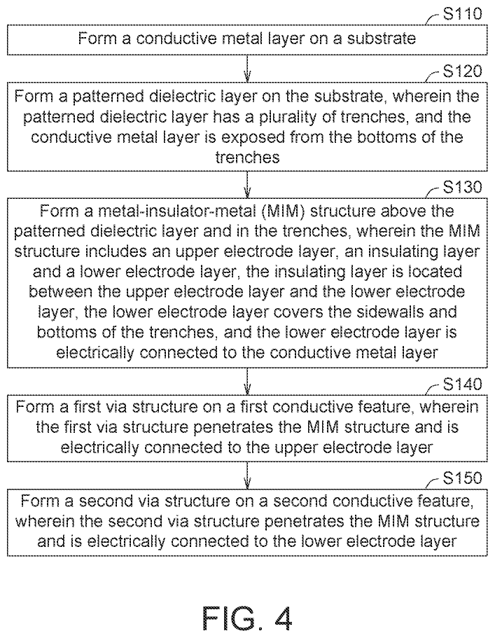

For details, please refer to FIG. 1 and FIG. 4. FIG. 4 illustrates a flow chart of a method of manufacturing a MIM capacitor Ct according to an embodiment of the present disclosure. In step S110, a conductive metal layer 110 is formed on a substrate 101. In step S120, a patterned dielectric layer (i.e., 112) is formed on the substrate 101. The patterned dielectric layer (i.e., 112) has a plurality of trenches 114, and the conductive metal layer 110 is exposed from the bottoms of the trenches 114. In step S130, a metal-insulator-metal (MIM) structure 120 is formed over the patterned dielectric layer 112 and in the trenches 114. The MIM structure 120 includes an upper electrode layer 121, an insulating layer 122 and a lower electrode layer 123. The insulating layer 122 is located between the upper electrode layer 121 and the lower electrode layer 123. The lower electrode layer 123 covers the sidewalls and the bottoms of the trenches 114, and the lower electrode layer 123 is electrically connected to the conductive metal layer 110. In step S140, a first via structure 106 is formed on a first conductive feature 104. The first via structure 106 penetrates the MIM structure 120 and is electrically connected to the upper electrode layer 121. In step S150, a second via structure 107 is formed on a second conductive feature 105. The second via structure 107 penetrates the MIM structure 120 and is electrically connected to the lower electrode layer 123. Therefore, the upper electrode layer 121 and the lower electrode layer 123 can form a MIM capacitor Ct between the first via structure 106 and the second via structure 107.

The present disclosure relates to a MIM capacitor, a semiconductor device having the same and a manufacturing method thereof. The MIM capacitor is filled in the trenches to increase the capacitance of the MIM capacitor; however, the current must pass through a tortuous path inside the capacitor so that the resistance of the current is high. In order to reduce the resistance of the MIM capacitor, a conductive metal layer is added at the bottoms of the trenches to make the current reach each of the trenches faster from the conductive metal layer. Furthermore, in order to reduce the parasitic capacitance effect, a low-k dielectric layer or a thicker etch stop layer is added between the conductive metal layer and adjacent conductive features.

According to some embodiments of the present disclosure, a manufacturing method of a MIM capacitor is provided. The manufacturing method includes the following steps. A conductive metal layer is formed on a substrate. A patterned dielectric layer is formed on the substrate. The patterned dielectric layer has a plurality of trenches, and the conductive metal layer is exposed at the bottom of the trenches. A metal-insulator-metal (MIM) structure is formed above the patterned dielectric layer and in the trenches. The MIM structure includes an upper electrode layer, an insulating layer and a lower electrode layer. The insulating layer is located on the upper electrode layer and the lower electrode layer, wherein the lower electrode layer covers the sidewalls and bottoms of the trenches, and the lower electrode layer is electrically connected to the conductive metal layer.

According to some embodiments of the present disclosure, a MIM capacitor is provided, The MIM capacitor includes a conductive metal layer and a metal-insulator-metal (MIM) structure. The conductive metal layer is disposed on a substrate. The MIM structure is disposed on a patterned dielectric layer, the patterned dielectric layer covers the substrate, and the patterned dielectric layer has a plurality of trenches, and the conductive metal layer is exposed at the bottom of the trenches. The MIM structure includes an upper electrode layer, an insulating layer and a lower electrode layer. The insulating layer is located between the upper electrode layer and the lower electrode layer, wherein the lower electrode layer covers the sidewalls and bottoms of the trenches, and The lower electrode layer is electrically connected to the conductive metal layer.

According to some embodiments of the present disclosure, a semiconductor device is provided. The semiconductor device includes a substrate, a first conductive feature, a second conductive feature, a first via structure, a second via structure, a conductive metal layer, and a metal-insulator-metal (MIM) structure. The first conductive feature and the second conductive feature are disposed on the substrate. The first via structure is formed on the first conductive feature and the second via structure is formed on the second conductive feature. The conductive metal layer is disposed on the substrate. The MIM structure is disposed on a patterned dielectric layer, the patterned dielectric layer covers the substrate, and the patterned dielectric layer has a plurality of trenches, and the conductive metal layer is exposed at the bottom of the trenches, wherein the MIM The structure includes an upper electrode layer, an insulating layer and a lower electrode layer. The insulating layer is located between the upper electrode layer and the lower electrode layer, wherein the lower electrode layer covers the sidewalls and bottoms of the trenches, and the lower electrode layer The electrode layer is electrically connected to the conductive metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a metal-insulator-metal (MIM) capacitor, comprising:
forming a conductive metal layer on a substrate;
forming a patterned dielectric layer on the substrate, the patterned dielectric layer having a plurality of trenches, and the conductive metal layer being exposed from bottoms of the trenches; and
forming a MIM structure on the patterned dielectric layer and in the trenches, the MIM structure comprising an upper electrode layer, an insulating layer and a lower electrode layer, the insulating layer being located between the upper electrode layer and the lower electrode layer, wherein the lower electrode layer covers sidewalls and the bottoms of the trenches, and the lower electrode layer is electrically connected to the conductive metal layer.

2. The method according to claim 1, wherein the upper electrode layer and the lower electrode layer are electrically isolated from each other.

3. The method according to claim 1, wherein before forming the conductive metal layer on the substrate, the method further comprises forming a low-k dielectric layer on the substrate, and the conductive metal layer is disposed on the low-k dielectric layer.

4. The method according to claim 1, wherein forming the patterned dielectric layer on the substrate comprises forming a first patterned photoresist layer on a first interlayer dielectric (ILD) layer, etching the first ILD layer not covered by the first patterned photoresist layer to form the trenches.

5. The method according to claim 4, wherein forming the MIM structure comprises removing the first patterned photoresist layer, forming the lower electrode layer on the first ILD layer and in the trenches, and forming the insulating layer and the upper electrode layer over the lower electrode layer, wherein the insulating layer and the upper electrode layer are recessed and filled in the trenches.

6. The method according to claim 5, further comprising forming a second ILD layer on the first ILD layer, the second ILD layer covering the MIM structure, so that the MIM structure is embedded between the first ILD layer and the second ILD layer.

7. The method according to claim 6, further comprising forming a second patterned photoresist layer on the second ILD layer, and etching the first ILD layer and the second ILD layer not covered by the second patterned photoresist layer to form a plurality of through holes.

8. The method according to claim 7, wherein after forming the through holes, the method further comprises filling a conductive material into the through holes, and depositing the conductive material on corresponding conductive features to form a first via structure and a second via structure.

9. The method according to claim 8, wherein the first via structure penetrates the MIM structure and is electrically connected to the upper electrode layer, and the second via structure penetrates the MIM structure and is electrically connected to the lower electrode layer.

10. A metal-insulator-metal (MIM) capacitor, comprising:
a conductive metal layer disposed on a substrate; and
a MIM structure disposed on a patterned dielectric layer, wherein the patterned dielectric layer covers the substrate, and the patterned dielectric layer has a plurality of trenches, the conductive metal layer are exposed from bottoms of the trenches;
wherein the MIM structure comprises an upper electrode layer, an insulating layer and a lower electrode layer, the insulating layer is located between the upper electrode layer and the lower electrode layer, the lower electrode layer covers sidewalls and the bottoms of the trenches, and the lower electrode layer is electrically connected to the conductive metal layer.

11. The MIM capacitor according to claim 10, wherein the upper electrode layer and the lower electrode layer are electrically isolated from each other.

12. The MIM capacitor according to claim 10, further comprising a low-k dielectric layer disposed on the substrate, and the conductive metal layer is disposed on the low-k dielectric layer.

13. The MIM capacitor according to claim 10, wherein the conductive metal layer is made of same material as the lower electrode layer.

14. The MIM capacitor according to claim 10, wherein the upper electrode layer comprises a plurality of vertical electrode portions filled in the trenches and a horizontal electrode portion laterally connected to the vertical electrode portions.

15. A semiconductor device, comprising:
a substrate;
a first conductive feature disposed on the substrate;
a second conductive feature disposed on the substrate;
a first via structure formed on the first conductive feature;
a second via structure formed on the second conductive feature;
a conductive metal layer disposed on the substrate; and
a metal-insulator-metal (MIM) structure disposed on a patterned dielectric layer, the patterned dielectric layer covers the substrate, and the patterned dielectric layer has a plurality of trenches, the conductive metal layer is exposed from bottoms of the trenches, wherein the MIM structure comprises an upper electrode layer, an insulating layer and a lower electrode layer, the insulating layer is located between the upper electrode layer and the lower electrode layer, wherein the lower electrode layer covers sidewalls and the bottoms of the trenches, and the lower electrode layer is electrically connected to the conductive metal layer.

16. The semiconductor device according to claim 15, wherein the upper electrode layer and the lower electrode layer are electrically isolated from each other.

17. The semiconductor device according to claim 15, further comprising a low-k dielectric layer disposed on the substrate, and the conductive metal layer is disposed on the low-k dielectric layer.

18. The semiconductor device according to claim 15, wherein the conductive metal layer is made of same material as the lower electrode layer.

19. The semiconductor device according to claim 15, wherein the upper electrode layer comprises a plurality of vertical electrode portions filled in the trenches and a horizontal electrode portion laterally connected to the vertical electrode portions.

20. The semiconductor device according to claim 15, wherein the first via structure penetrates the MIM structure and is electrically connected to the upper electrode layer, and the second via structure penetrates the MIM structure and is electrically connected to the lower electrode layer.
